(19) United States
(12) Patent Application Publication
(10) Pub. No.: US 2023/0037038 A1
(43) Pub. Date: Feb. 2, 2023

(54) DEPOSITION APPARATUS

(71) Applicant: Samsung Electronics Co., Ltd., Suwon-si (KR)

(72) Inventors: Byoungcheol HWANG, Suwon-si (KR); Sangwook LEE, Gwangju-si (KR); Sunghyup KIM, Hwaseong-si (KR); Keonwoo KIM, Yongin-si (KR); Junyoung CHOI, Suwon-si (KR); Sanghoon CHEONG, Suwon-si (KR)

(73) Assignee: Samsung Electronics Co., Ltd., Suwon-si (KR)

(21) Appl. No.: 17/702,105

(22) Filed: Mar. 23, 2022

(30) Foreign Application Priority Data
Jul. 27, 2021 (KR) 10-2021-0098497

(51) Int. Cl. C23C 16/455; C23C 16/458

(52) U.S. Cl. CPC C23C 16/45561; C23C 16/4585; C23C 16/45565; C23C 16/4586; H01L 21/6833

(57) ABSTRACT

A deposition apparatus, includes a chamber having at least one first gas inlet therein. A fixed chuck is installed in the chamber and an electrostatic chuck is installed on the fixed chuck. An edge ring is disposed on an edge of the electrostatic chuck. A shower head is disposed above the edge ring. A baffle is disposed above the shower head and an upper electrode is disposed above the baffle. A gas guide member is disposed above the upper electrode so that a flow path provided in the upper electrode and the first gas inlet are connected. The gas guide member has a flow path hole penetrating in upward and downward directions, and a plurality of guide holes are provided on an inner surface of the gas guide member.

### CROSS-REFERENCE TO RELATED APPLICATION

This application claims the priority and benefit of Korean Patent Application No. 10-2021-0098497, filed on Jul. 27, 2021, with the Korean Intellectual Property Office, the inventive concepts of which are incorporated herein by reference.

### BACKGROUND

### 1. Field

The present inventive concepts relate to a deposition apparatus.

### 2. Description of Related Art

In a deposition apparatus for the nucleation of metal, gases (Ar, WF6) are injected from an upper portion of a chamber and supplied to a gas guide member, and boron (B2H6), a reducing material, is supplied through a side surface of the gas guide member. In addition, the gas supplied to the gas guide member to supply the gas to an upper surface of the wafer is mixed in a flow path hole of the gas guide member. Meanwhile, boron (B2H6) gas, a gas supplied to a side surface of the gas guide member, is introduced into the flow path hole through a slit connected to the flow path hole while passing through an inside of the gas guide member.

However, there may be a problem in that the gas supplied to the wafer may not be uniformly supplied to the wafer by the boron gas introduced into a side injection port of the gas guide member.

### SUMMARY

An aspect of the present inventive concepts is to provide a deposition apparatus capable of reducing deflection of gas supplied to a wafer and supplying the gas to the wafer.

According to an aspect of the present inventive concepts, a deposition apparatus includes: a chamber having at least one first gas inlet therein and having an interior space; a fixed chuck installed in the chamber; an electrostatic chuck installed on the fixed chuck; an edge ring installed on the electrostatic chuck to be disposed on an edge of the electrostatic chuck; a shower head disposed above the edge ring; a baffle disposed above the shower head; an upper electrode disposed above the baffle; a gas guide member disposed above the upper electrode so that a flow path provided in the upper electrode and the first gas inlet are connected, wherein the gas guide member has a hollow cylindrical shape having a flow path hole penetrating in upward and downward directions, and at least two side supply ports into which gas is introduced are provided on an outer surface of the gas guide member, and a plurality of guide holes for allowing the gas introduced through the side supply port to be introduced into the flow path hole of the gas guide member may be provided on an inner surface of the gas guide member, wherein the gas introduced into the first gas inlet and the side supply port may be mixed in the flow path hole.

### BRIEF DESCRIPTION OF DRAWINGS

The above and other aspects, features, and advantages of the present inventive concepts will be more clearly understood from the following detailed description taken in conjunction with the accompanying drawings, in which:

FIG. 1 is a schematic perspective view illustrating a deposition apparatus according to an example embodiment;

FIG. 2 is a partially exploded perspective view illustrating a section of a deposition apparatus according to an example embodiment;

FIG. 3 is a cross-sectional view illustrating a gas guide member provided in a deposition apparatus according to an example embodiment;

FIG. 4 is a cross-sectional view illustrating a gas guide portion of a gas guide member provided in a deposition apparatus according to an example embodiment;

FIG. 5 is a schematic view illustrating the airflow distribution by the gas guide member according to the prior art;

FIG. 6 is an explanatory diagram illustrating airflow distribution by a gas guide member of a deposition apparatus according to an example embodiment of the present inventive concepts;

FIG. 7 is an explanatory diagram illustrating a mass fraction of a B₂H₆ gas distributed under a baffle by a gas guide member according to the prior art in a top view;

FIG. 8 is an explanatory diagram illustrating a mass fraction of a B₂H₆ gas distributed under a baffle by a gas guide member of a deposition apparatus according to an example embodiment of the present inventive concepts in a top view;

FIG. 9 is a schematic view illustrating velocity distribution in a vicinity of the upper/side airflow mixing region of the gas guide member according to the prior art;

FIG. 10 is an explanatory diagram illustrating velocity distribution in a vicinity of an upper/side airflow mixing region of a gas guide member according to an example embodiment of the present inventive concepts;

FIG. 11 is an explanatory diagram illustrating a deposition thickness distribution on an upper surface of a wafer when a process is performed using a gas guide member according to the prior art;

FIG. 12 is an explanatory diagram illustrating a deposition thickness distribution on the upper surface of a wafer when a process is performed using a gas guide member according to an example embodiment of the present inventive concepts;

FIG. 13 is a cross-sectional view illustrating a gas guide member provided in a deposition apparatus according to an example embodiment;

FIG. 14 is a cross-sectional view illustrating a gas guide member provided in a deposition apparatus according to an example embodiment;

FIG. 15 is a cross-sectional view illustrating a gas guide member provided in a deposition apparatus according to an example embodiment;

FIG. 16 is a cross-sectional view illustrating a gas guide member provided in a deposition apparatus according to an example embodiment; and

FIG. 17 is a cross-sectional view illustrating a gas guide member provided in a deposition apparatus according to an example embodiment.

### DETAILED DESCRIPTION

Hereinafter, example embodiments of the present inventive concepts will be described with reference to the accompanying drawings as follows.

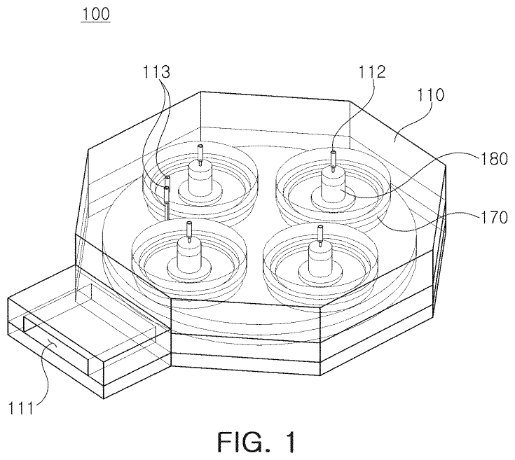

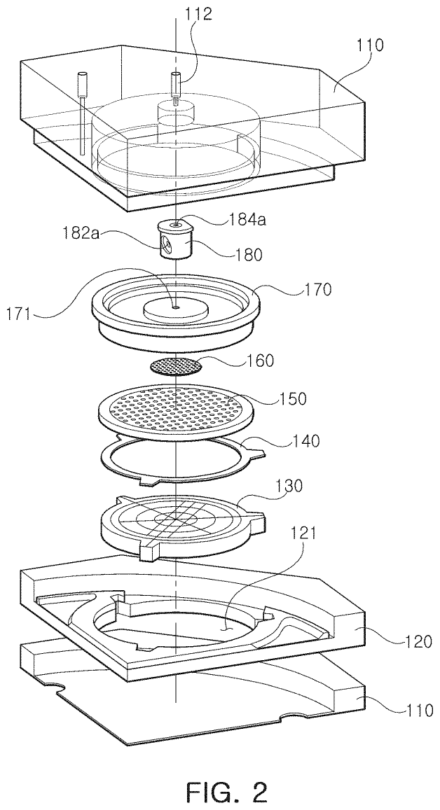

FIG. 1 is a schematic perspective view illustrating a deposition apparatus according to an example embodiment, and FIG. 2 is a partially exploded perspective view illustrating a deposition apparatus according to an example embodiment.

Referring to FIGS. 1 and 2, a deposition apparatus 100 according to an example embodiment includes a chamber 110, a fixed chuck 120, an electrostatic chuck 130, an edge ring 140, a shower head 150, a baffle 160, an upper electrode 170, and a gas guide member 180.

The chamber 110 has, for example, an internal space capable of performing a deposition apparatus for four wafers (not shown). Meanwhile, the chamber 110 may be provided with an entry-exit port 111 for entry and exit of the wafer, and the entry-exit port 111 may be closed during the process. Meanwhile, the chamber 110 may be provided with a first gas inlet 112 for supplying gas to the wafer on an upper surface thereof. A plurality of first gas inlets 112 may be provided according to the number of wafers accommodated in the chamber 110. For example, four first gas inlets 112 may be provided in an upper end portion of the chamber 110. In addition, the chamber 110 may be provided with a second gas inlet 113 for supplying gas to a side surface of the gas guide member 180 to be described later.

As an example, the first and second gas inlets 112 and 113 are connected to a gas supply source through a gas supply line (not shown), and a configuration for controlling a flow rate on the gas supply line, for example, a valve and a mass flow controller (MFC) can be installed.

The fixed chuck 120 is installed in the chamber 110, and an installation groove 121 in which the electrostatic chuck 130 is installed is formed in the fixed chuck 120. As an example, the fixed chuck 120 may be made of a conductive material having excellent electrical conductivity, such as aluminum (Al), and the fixed chuck 120 may have a shape corresponding to the shape of the chamber 110.

The electrostatic chuck 130 is fixedly installed in the installation groove 121 of the fixed chuck 120. As an example, the electrostatic chuck 130 may be formed of a circular plate made of an insulating material such as ceramic. In addition, the electrostatic chuck 130 may include two polyimide-based films and a conductive thin film therebetween. The conductive thin film may be connected to a high-voltage DC power supply (not shown) external of the chamber 110. When a predetermined voltage is applied to the conductive thin film from a high-voltage DC power supply, electric charges are generated on a surface of the polyimide-based film to generate Coulomb force to fix the wafer to an upper surface of the electrostatic chuck 130. Accordingly, the wafer loaded into the chamber 110 may be seated on the electrostatic chuck 130.

The edge ring 140 is installed on the electrostatic chuck 130 to be disposed on an edge of the electrostatic chuck 130. As an example, the edge ring 140 may have a circular ring shape. The edge ring 140 may be made of a conductive material such as metal. Meanwhile, the edge ring 140 serves to improve uniformity of a plasma sheath formed on the wafer by moving active ions or radicals of a source plasma to a periphery of the wafer. Accordingly, the source plasma formed in the internal space of the chamber 110 can be intensively formed in an upper region of the wafer. As a further example, the edge ring 140 may be made of any one of silicon (Si), silicon carbide (SiC), silicon oxide (SiO₂), and aluminum oxide (AlO₂).

The shower head 150 is disposed above the edge ring 140. As an example, the shower head 150 has a circular plate shape corresponding to the shape of the wafer, and serves to uniformly spread the gas supplied to the chamber 110 downwardly. To this end, a plurality of holes may be formed in the shower head 150.

The baffle 160 is disposed above the shower head 150, and serves to disperse the gas introduced into the shower head 150 to a wider region. For this purpose, a plurality of holes may be formed in the baffle 160 as well. As an example, the baffle 160 may have a size disposed in a central portion of the shower head 150.

The upper electrode 170 is disposed above the baffle 160. As an example, the upper electrode 170 may include a flow path 171 through which the supplied gas flows, and the gas is provided to the baffle 160 side through the flow path 171. In addition, the upper electrode 170 is disposed above the electrostatic chuck 130 to face the electrostatic chuck 130. As an example, the upper electrode 170 may be made of a silicon material.

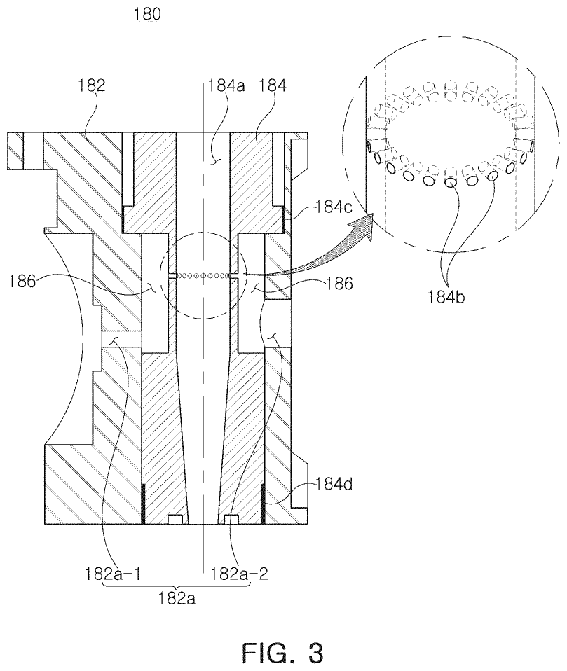

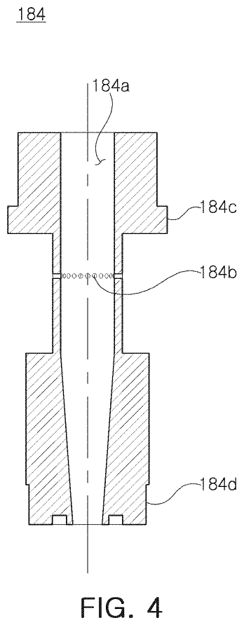

The gas guide member 180 is disposed above the upper electrode 170 so that a flow path of the upper electrode 170 and the first gas inlet 112 are connected to each other. As an example, the gas guide member 180 may be fixedly installed on an upper surface of the upper electrode 170. Meanwhile, as shown in more detail in FIGS. 3 and 4, the gas guide member 180 includes a body 182 having a side supply port 182a, and a gas guide portion 184 insertedly coupled to an inside of the body 182, and having a flow path hole 184a and a guide hole 184b. In other words, the gas guide member 180 may have a hollow cylindrical shape having a flow path hole 184a penetrating in upward and downward directions, and may be provided with at least two side supply ports 182a into which gas is introduced on an outer surface. In addition, a plurality of guide holes 184b may be provided on an inner surface of the gas guide member 180 and are configured to introduce gas from the side supply port 182a and into the flow path hole 184a of the gas guide member 180. Meanwhile, the gas introduced into the first gas inlet 112 and the side supply port 182a may be mixed in the flow path hole 184a.

As an example, the plurality of guide holes 184b may be disposed to form one row. In addition, the plurality of guide holes 184b may be circumferentially spaced apart from each other to have the same angle therebetween. As an example, the plurality of guide holes 184b may have a diameter of 1 to 2 mm, and a total of 24 guide holes may be provided such that an angle therebetween with adjacent guide holes 184b is 15 degrees. However, the present inventive concept is not limited thereto, and the diameter and number of the plurality of guide holes 184b may be variously changed.

Meanwhile, the body 182 and the gas guide portion 184 form a flow path 186 through which the gas introduced into the side supply port 182a is discharged to the plurality of guide holes 184b. The flow path 186 is formed to have an internal space of a predetermined volume. In addition, the flow path 186 may have an annular shape and a rectangular cross-section. As described above, since the flow path 186 is formed to have an internal space of a predetermined volume, the gas introduced into the flow path 186 may be discharged to the plurality of guide holes 184b at a constant pressure. As an example, the plurality of guide holes 184b may be disposed in a central portion of the flow path 186 in approximately upward and downward directions.

Here, when the term for direction is defined, a circumferential direction refers to a direction which rotates along an inner circumferential surface of the gas guide portion 184, and upper and lower directions of the flow path 186 refer to a Z-axis direction of FIG. 1.

In addition, a first stepped portion 184c for bonding to a body 182 may be provided in an upper end portion of the outer circumferential surface of the gas guide portion 184, and a second stepped portion 184d for bonding to the body 182 may be provided in a lower end portion of the outer circumferential surface of the gas guide portion 184. The first and second stepped portions 184c and 184d may be bonded to the body 182 by welding. However, the present inventive concepts are not limited thereto and may be bonded to the first and second stepped portions 184c and 184d by an adhesive.

Meanwhile, the flow path hole 184a of the gas guide portion 184 may be formed such that an upper diameter thereof is larger than a lower diameter thereof, and a lower end portion of the flow path hole 184a may have a smaller diameter toward the lower side. Accordingly, the gas introduced from the first gas inlet 112 and the gas introduced into the guide holes 184b can be more smoothly supplied to the upper electrode 170, the baffle 160, and the shower head 150, which are disposed therebelow.

The side supply port 182 provided in the body 183 may include a first side supply port 182a-1 connected to the flow path 186 formed by the body 182 and the gas guide portion 184 and a second side supply port 182a-2 having a larger size than the first side supply port 182a-1 and connected to the flow path 186. As an example, the first side supply port 182a-1 serves as a passage through which gas used in a deposition process is introduced, and the second side supply port 182a-2 serves as a passage through which cleaning gas is introduced during maintenance and repair work of the deposition apparatus 100 after the process is completed.

During the deposition process, a valve (not shown) installed in a cleaning gas supply line (not shown) connected to the second side supply port 182a-2 may be closed to prevent a process gas from being introduced into the cleaning gas supply line, and during the maintenance and repair work by the cleaning gas, a valve(not shown) installed in the process gas supply line (not shown) connected to the first side supply port 182a-1 may be closed to prevent the cleaning gas from being introduced into the process gas supply line.

Meanwhile, the gas supplied through the first gas inlet 112 may be an Ar gas and a WF₆ gas, and the gas supplied through the side supply port 182a may be a B₂F₆ gas. However, the present inventive concepts are not limited thereto, and the supplied gas may be variously changed according to the process.

As described above, since the gas is supplied to the flow path hole 184a through the plurality of guide holes 184b having a circular hole shape, it is possible to prevent the supplied gas from being deflected and supplied downwardly.

Hereinafter, an operation of a deposition apparatus according to an example embodiment of the present inventive concepts will be described with reference to the drawings.

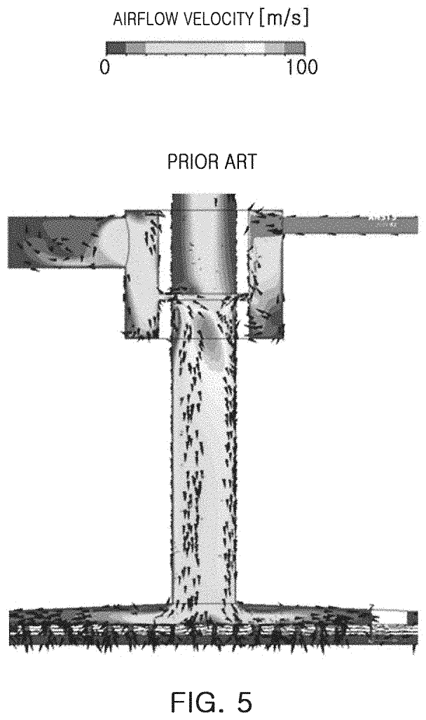

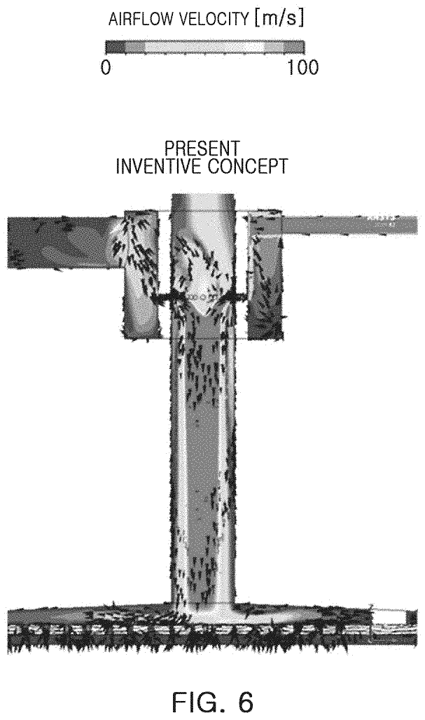

FIG. 5 is an explanatory diagram illustrating airflow distribution by a gas guide member according to the prior art, and FIG. 6 is an explanatory diagram illustrating airflow distribution by a gas guide member of a deposition apparatus according to an example embodiment of the present inventive concepts.

Meanwhile, FIGS. 5 and 6 are explanatory diagrams illustrating airflow distribution when Ar gas is injected into an upper portion of the gas guide member in the deposition process and Ar and B₂H₆ gas are mixed (mass ratio 8:1) and injected on a side surface thereof.

The gas guide member according to the prior art of FIG. 5 illustrates a case in which gas is supplied to a flow path hole through a slit-shaped communication hole, and

FIG. 6 illustrates a case in which gas is supplied through a plurality of guide holes in the gas guide member of the deposition apparatus according to an example embodiment of the present inventive concepts.

It can be seen that the deflection of the airflow formed below the gas guide member is improved in FIG. 6 as compared with FIG. 5. That is, when gas is supplied to the flow path hole 184a through the plurality of guide holes 184b, it can be seen that the airflow distribution is not deflected and the gas constantly flows downwardly.

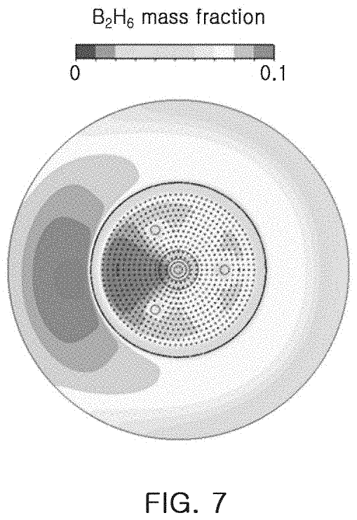

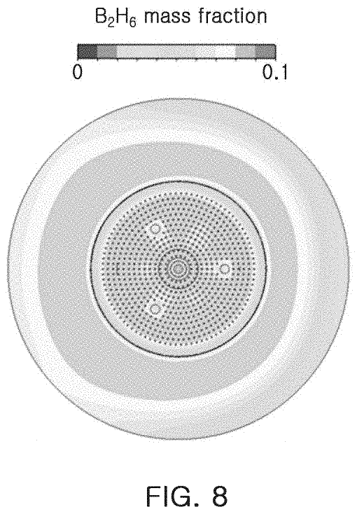

In addition, FIG. 7 is an explanatory diagram illustrating a mass fraction of B₂H₆ gas distributed under a baffle by a gas guide member according to the prior art in a top view. FIG. 8 is an explanatory diagram illustrating a mass fraction of a B₂H₆ gas distributed below a baffle by a gas guide member of a deposition apparatus according to an example embodiment of the present inventive concept in a top view.

Referring to FIGS. 7 and 8, it can be seen that the deflection of the airflow is significantly reduced in FIG. 8 as compared to FIG. 7 in which the airflow distributed below the baffle is deflected to a left side, as viewed in FIG. 7. Since the gas guide member according to the prior art supplies gas to the flow path hole through the slit-shaped communication hole, it is understood that a deflected airflow is generated as shown in FIG. 7, and since the gas is supplied to the flow path hole through a plurality of circumferentially spaced guide holes 184b, the deflection of the airflow is significantly reduced as compared to FIG. 7.

Meanwhile, if uniformity is defined for quantitative comparison, uniformity is (standard deviation of mass fraction/average value of mass fraction)×100. In this case, it can be seen that the uniformity is improved by 22.7% in the case of the gas guide member according to an example embodiment of the present inventive concept compared to the gas guide member according to the prior art.

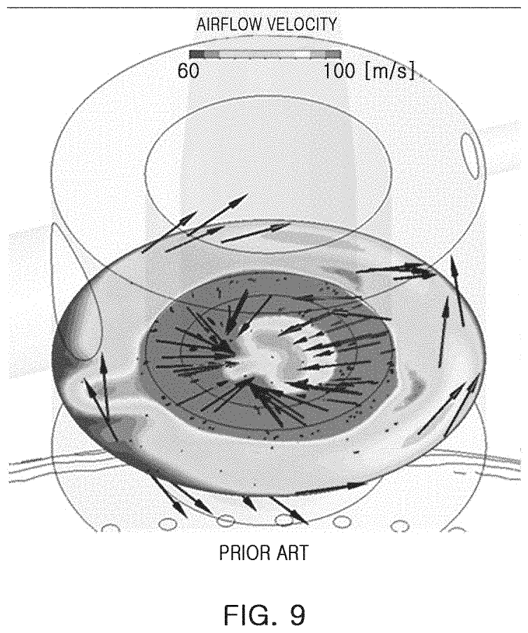

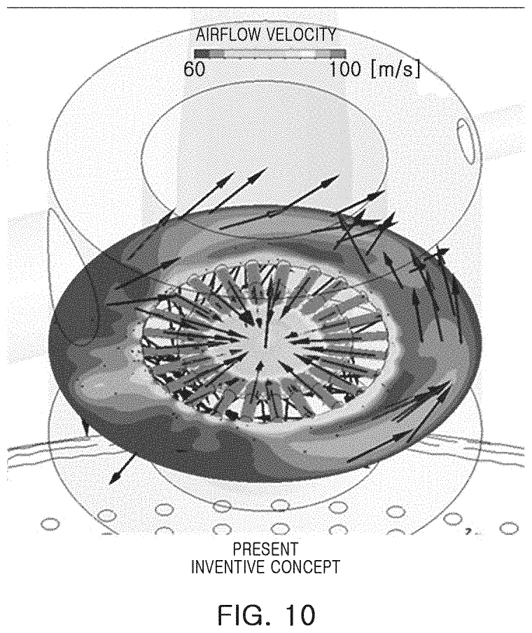

Further, FIG. 9 is an explanatory diagram illustrating velocity distribution in a vicinity of an upper/side airflow mixing region of the gas guide member according to the prior art, and FIG. 10 is an explanatory diagram illustrating velocity distribution in a vicinity of an upper/side airflow mixing region of the gas guide member 180 according to an example embodiment of the present inventive concepts.

Looking at a vector component (arrow) indicating a direction of the velocity shown in FIGS. 9 and 10, in the case of the gas guide member according to the prior art of FIG. 9, it can be seen that the vector component (arrow) indicating the direction of the velocity is deflected to one side with respect to a center, which means there is a high probability of deflection in forming downdrafts. On the other hand, in the case of the gas guide member according to an example embodiment of FIG. 10, it can be seen that the vector components (arrows) indicating the direction of the velocity all point toward the center, which indicates that the deflection is reduced when the downdraft is formed.

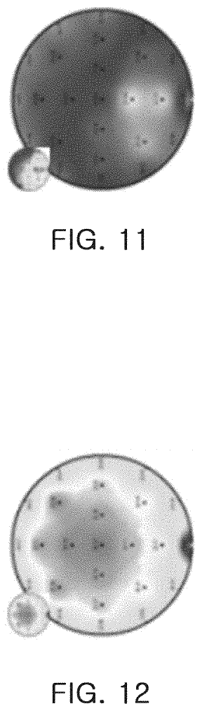

In addition, FIG. 11 is an explanatory diagram illustrating a deposition thickness distribution on an upper surface of a wafer when the process is performed with a gas guide member according to the prior art, and FIG. 12 is an explanatory diagram illustrating a deposition thickness distribution on the upper surface of the wafer when the process is performed with a gas guide member according to an example embodiment of the present inventive concepts.

As shown in FIG. 11, when the process is performed with the gas guide member according to the prior art, the deviation of the deposition thickness appears large on the upper surface of the wafer to the left and right, whereas as shown in FIG. 12, it can be seen that the thickness deviation appears high only in a central portion thereof when the process is performed with the gas guide member according to an example embodiment of the present inventive concept. As a result of calculating thickness uniformity for quantitative comparison, when the process was performed with the gas guide member according to an example embodiment of the present inventive concepts, it was confirmed that the thickness uniformity is improved by 10.4% (12%->1.6%) as compared to the case in which the process is performed with the gas guide member according to the prior art.

As described above, the deflection of the airflow formed below the gas guide member may be improved, and the deflection of the airflow distributed under the baffle may be remarkably reduced.

Furthermore, it can be seen that the velocity distribution near the upper/side airflow mixing region of the gas guide member is also improved, and the thickness variation of a deposition layer deposited on the upper surface of the wafer is improved.

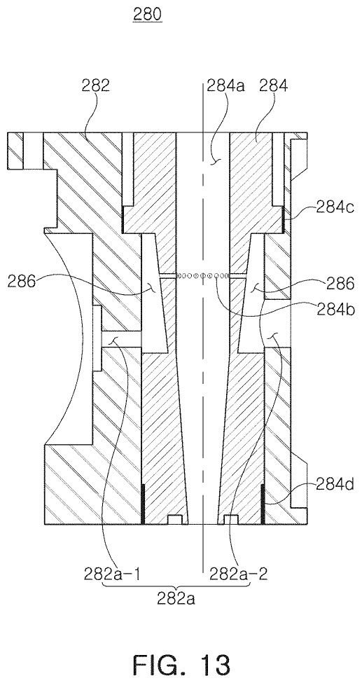

FIG. 13 is a cross-sectional view illustrating a gas guide member 280 provided in a deposition apparatus according to an example embodiment.

Referring to FIG. 13, a gas guide member 280 is disposed above the upper electrode 170 so that the passage 171 (refer to FIG. 2) of the upper electrode 170 (refer to FIG. 2) and the first gas inlet 112 (refer to FIG. 2) are connected to each other. As an example, the gas guide member 280 may be fixedly installed on an upper surface of the upper electrode 170. Meanwhile, the gas guide member 280 includes a body 282 having a side supply port 282a and gas guide portion 280 insertedly coupled to an inside of the body 282 and having a flow path hole 284a and a plurality of guide holes 284b. In other words, the gas guide member 280 has a hollow cylindrical shape having a flow path hole 284a penetrating in upward and downward directions, and at least two side supply ports 282a through which gas is introduced can be provided on an external side surface. In addition, a plurality of guide holes 284b may be provided on an inner surface of the gas guide member 280 to allow the gas introduced through a side supply port 282a to flow into the flow path hole 284a of the gas guide member 280. Meanwhile, the gas introduced into the first gas inlet 112 and the side supply port 282a may be mixed in the flow path hole 284a.

As an example, the plurality of guide holes 284b may be disposed to form one row. In addition, the plurality of guide holes 284b may be circumferentially spaced apart from each other to have the same angle therebetween.

Meanwhile, the body 282 and the gas guide portion 284 form a flow path 286 through which the gas introduced through the side supply port 282a is discharged to the plurality of guide holes 284b. The flow path 286 is formed to have an internal space of a predetermined volume. In addition, the flow path 286 may have an annular shape and a trapezoidal cross-section. As described above, since the flow path 286 is formed to have an internal space of a predetermined volume, the gas introduced into the flow path 286 may be discharged to the plurality of guide holes 284b at a constant pressure. As an example, the plurality of guide holes 284b may be disposed in a central portion of the flow path 286 in approximately upper and lower directions.

In addition, a first stepped portion 284c for bonding to the body 282 may be provided in an upper end portion of an outer circumferential surface of the gas guide portion 284, and a second stepped portion 284d for bonding to the body 282 may be provided in a lower end portion of the outer circumferential surface of the gas guide portion 284. The first and second stepped portions 284c and 284d may be bonded to the body 282 by welding. However, the present inventive concept is not limited thereto and may be bonded to the first and second stepped portions 284c and 284d by an adhesive.

Meanwhile, a diameter of an upper portion of a flow path hole 284a of the gas guide portion 284 is larger than a diameter of a lower portion thereof, and the diameter of the lower end portion of the flow path hole 284a may decrease toward a lower side.

Accordingly, the gas introduced from the first gas inlet 112 and the gas introduced into the guide hole 284b may be more smoothly supplied to the upper electrode 170, the baffle 160 (refer to FIG. 2), and the showerhead 150, which are disposed therebelow.

The side supply port 282a provided in the body 282 may include a first side supply port 282a-1 connected to the flow path 286 formed by the body 282 and the gas guide portion 284 and a second side supply port 282a-2 having a larger size than the first side supply port 282a-1 and connected to the flow path 286. As an example, the first side supply port 282a-1 serves to a passage through which a gas used for the deposition process is introduced, and the second side supply port 282a-2 serves as a passage through which cleaning gas is introduced during maintenance and repair work of the deposition apparatus after the process is completed.

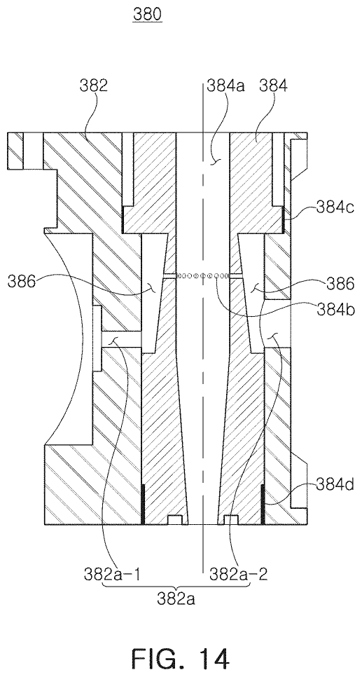

FIG. 14 is a cross-sectional view illustrating a gas guide member 380 provided in a deposition apparatus according to an example embodiment.

Referring to FIG. 14, a gas guide member 380 is disposed above the upper electrode 170 so that the passage 171 (refer to FIG. 2) of the upper electrode 170 (refer to FIG. 2) and the first gas inlet 112 (refer to FIG. 2) are connected to each other. As an example, the gas guide member 380 may be fixedly installed on an upper surface of the upper electrode 170. Meanwhile, the gas guide member 380 includes a body 382 having a side supply port 382a and a gas guide portion 384 insertedly coupled to an inside of the body 382 and having a flow path hole 384a and a plurality of guide holes 384b. In other words, the gas guide member 380 has a hollow cylindrical shape having a flow path hole 384a penetrating in upward and downward directions, and at least two side supply ports 382a through which gas is introduced may be provided on an external side surface thereof. In addition, a plurality of guide holes 384b for allowing gas introduced through the side supply port 382a to be introduced into the flow path hole 384a of the gas guide member 380 may be provided on an inner surface of the gas guide member 380. Meanwhile, the gas introduced into the first gas inlet 112 and the side supply port 382a may be mixed in the flow path hole 384a.

As an example, the plurality of guide holes 384b may be disposed to form one row. In addition, the plurality of guide holes 384b may be circumferentially spaced apart from each other to have the same angle therebetween.

Meanwhile, the body 382 and the gas guide portion 384 form a flow path 386 through which the gas introduced through the side supply port 382a is discharged to the plurality of guide holes 384b. The flow path 386 is formed to have an internal space of a predetermined volume. In addition, the flow path 386 may have an annular shape and a trapezoidal cross-section. As described above, since the flow path 386 is formed to have an internal space of a predetermined volume, the gas introduced into the flow path 386 may be discharged to the plurality of guide holes 384b at a constant pressure. As an example, the plurality of guide holes 384b may be disposed in a central portion of the flow path 386 in approximately upper and lower directions.

In addition, a first stepped portion 384c for bonding to the body 382 may be provided in an upper end portion of an outer circumferential surface of the gas guide portion 384, and a second stepped portion 384d for bonding to the body 382 may be provided in a lower end portion of the outer circumferential surface of the gas guide portion 384. The first and second stepped portions 384c and 384d may be bonded to the body 382 by welding. However, the present inventive concept is not limited thereto and may be bonded to the first and second stepped portions 384c and 384d by an adhesive.

Meanwhile, a diameter of an upper portion of a flow path hole 384a of the gas guide portion 384 is larger than a diameter of a lower portion thereof, and the diameter of the lower end portion of the flow path hole 384a may decrease toward a lower side.

Accordingly, the gas introduced from the first gas inlet 112 and the gas introduced into the guide hole 384b may be more smoothly supplied to the upper electrode 170, the baffle 160 (refer to FIG. 2), and the showerhead 150, which are disposed therebelow.

The side supply port 382a provided in the body 382 may include a first side supply port 382a-1 connected to the flow path 386 formed by the body 382 and the gas guide portion 384 and a second side supply port 382a-2 having a larger size than the first side supply port 382a-1 and connected to the flow path 386. As an example, the first side supply port 382a-1 serves to a passage through which a gas used for the deposition process is introduced, and the second side supply port 382a-2 serves as a passage through which cleaning gas is introduced during maintenance and repair work of the deposition apparatus after the process is completed.

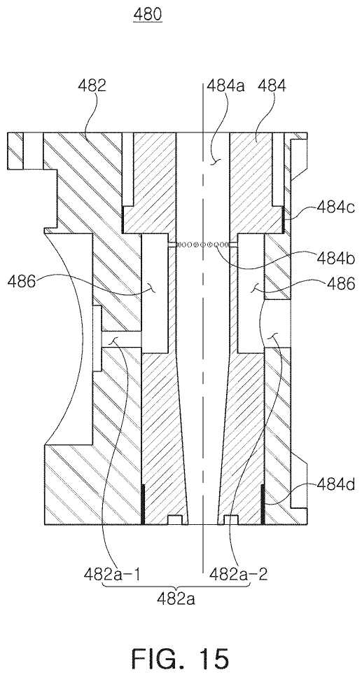

FIG. 15 is a cross-sectional view illustrating a gas guide member 480 provided in a deposition apparatus according to an example embodiment.

Referring to FIG. 15, a gas guide member 480 is disposed above the upper electrode 170 so that the passage 171 (refer to FIG. 2) of the upper electrode 170 (refer to FIG. 2) and the first gas inlet 112 (refer to FIG. 2) are connected to each other. As an example, the gas guide member 480 may be fixedly installed on an upper surface of the upper electrode 170. Meanwhile, the gas guide member 480 includes a body 482 having a side supply port 482a and a gas guide portion 484 insertedly coupled to an inside of the body 482 and having a flow path hole 484a and a plurality of guide holes 484b. In other words, the gas guide member 480 has a hollow cylindrical shape having a flow path hole 484a penetrating in upward and downward directions, and at least two side supply ports 482a into which gas is introduced may be provided on an external side surface thereof. In addition, a plurality of guide holes 484b for allowing gas introduced through the side supply port 482a to be introduced into the flow path hole 484a of the gas guide member 480 may be provided on an inner surface of the gas guide member 480. Meanwhile, the gas introduced into the first gas inlet 112 and the side supply port 482a may be mixed in the flow path hole 484a.

As an example, the plurality of guide holes 484b may be disposed to form one row. In addition, the plurality of guide holes 484b may be circumferentially spaced apart from each other to have the same angle therebetween.

Meanwhile, the body 482 and the gas guide portion 484 form a flow path 486 through which the gas introduced through the side supply port 482a flows out to the plurality of guide holes 484b. The flow path 486 is formed to have an internal space of a predetermined volume. In addition, the flow path 486 may have an annular shape and a trapezoidal cross-section. As described above, since the flow path 486 is formed to have an internal space of a predetermined volume, the gas introduced into the flow path 486 may be discharged to the plurality of guide holes 484b at a constant pressure. As an example, the plurality of guide holes 484b may be in an upper end portion of the flow path 486 in approximately upper and lower directions.

In addition, a first stepped portion 484c for bonding to the body 482 may be provided in an upper end portion of an outer circumferential surface of the gas guide portion 484, and a second stepped portion 484d for bonding to the body 482 may be provided in a lower end portion of the outer circumferential surface of the gas guide portion 484. The first and second stepped portions 484c and 484d may be bonded to the body 482 by welding. However, the present inventive concept is not limited thereto and may be bonded to the first and second stepped portions 484c and 484d by an adhesive.

Meanwhile, a diameter of an upper portion of a flow path hole 484a of the gas guide portion 484 is larger than a diameter of a lower portion thereof, and the diameter of the lower end portion of the flow path hole 484a may decrease toward a lower side.

Accordingly, the gas introduced from the first gas inlet 112 and the gas introduced into the guide hole 484b may be more smoothly supplied to the upper electrode 170, the baffle 160 (refer to FIG. 2), and the showerhead 150, which are disposed therebelow.

The side supply port 482a provided in the body 482 may be provided with a first side supply port 482a-1 connected to the flow path 486 formed by the body 482 and the gas guide portion 484 and a second side supply port 482a-2 having a larger size than the first side supply port 482a-1 and connected to the flow path 486. As an example, the first side supply port 482a-1 serves to a passage through which a gas used for the deposition process is introduced, and the second side supply port 482a-2 serves as a passage through which cleaning gas is introduced during maintenance and repair work of the deposition apparatus after the process is completed.

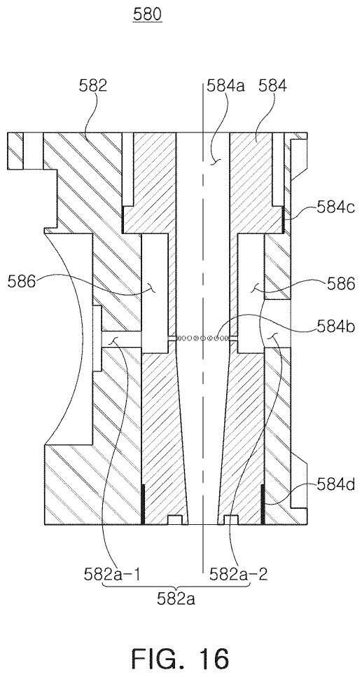

FIG. 16 is a cross-sectional view illustrating a gas guide member 580 provided in a deposition apparatus according to an example embodiment.

Referring to FIG. 16, a gas guide member 580 is disposed above the upper electrode 170 such that the path 171 (refer to FIG. 2) of the upper electrode 170 (see FIG. 2) and the first gas inlet 112 (refer to FIG. 2) are connected to each other. As an example, the gas guide member 580 may be fixedly installed on an upper surface of the upper electrode 170. Meanwhile, the gas guide member 580 includes a body 582 having a side supply port 582a, and a gas guide portion 584 insertedly coupled to an inside of the body 582 and having a flow path hole 584a and a plurality of guide holes 584b. In other words, the gas guide member 580 has a hollow cylindrical shape having a flow path hole 584a penetrating in upward and downward directions, and at least two side supply ports 582a into which gas is introduced may be provided on an external side surface thereof. In addition, a plurality of guide holes 584b for allowing gas introduced through the side supply port 582a to flow into the flow path hole 584a of the gas guide member 580 may be provided on an inner surface of the gas guide member 580. Meanwhile, the gas introduced into the first gas inlet 112 and the side supply port 582a may be mixed in the flow path hole 584a.

As an example, the plurality of guide holes 584b may be disposed to form one row. In addition, the plurality of guide holes 584b may be circumferentially spaced apart from each other to have the same angle therebetween.

Meanwhile, the body 582 and the gas guide portion 584 form a flow path 586 through which the gas introduced through the side supply port 582a flows out to the plurality of guide holes 584b. The flow path 586 is formed to have an internal space of a predetermined volume. In addition, the flow path 586 may have an annular shape and a rectangular cross-section. As described above, since the flow path 586 is formed to have an internal space of a predetermined volume, the gas introduced into the flow path 586 may be discharged to the plurality of guide holes 584b at a constant pressure. As an example, the plurality of guide holes 584b may be in a lower end portion of the flow path 586.

In addition, a first stepped portion 584c for bonding to the body 582 may be provided in an upper end portion of an outer circumferential surface of the gas guide portion 584, and a second stepped portion 584d for bonding to the body 582 may be provided in a lower end portion of the outer circumferential surface of the gas guide portion 584. The first and second stepped portions 584c and 584d may be bonded to the body 582 by welding. However, the present inventive concept is not limited thereto, and may be bonded to the first and second stepped portions 584c and 584d by an adhesive.

Meanwhile, a diameter of an upper portion of the flow path hole 584a of the gas guide portion 584 may be formed to be larger than a diameter of a lower portion thereof, and a lower end portion of the flow path hole 584a may have a smaller diameter toward a lower side. Accordingly, the gas introduced from the first gas inlet 112 and the gas introduced into the guide hole 584b may be more smoothly supplied to the lower upper electrode 170, the baffle 160 (refer to FIG. 2), and the shower head (refer to FIG. 2).

The side supply port 582a provided in the body 582 may include a first side supply port 582a-1 connected to the flow path 586 formed by the body 582 and the gas guide portion 584 and, a second side supply port 582a-2 that is larger than the first side supply port 582a-1 and is connected to the flow path 586. As an example, the first side supply port 582a-1 serves as a passage through which a gas used for the deposition process is introduced, and the second side supply port 582a-2 serves as a passage through which cleaning gas is introduced during maintenance and repair work of the deposition apparatus after the process is completed.

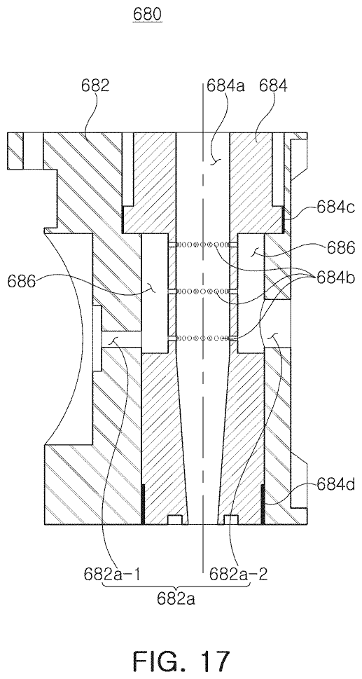

FIG. 17 is a cross-sectional view illustrating a gas guide member 680 provided in a deposition apparatus according to an example embodiment.

Referring to FIG. 17, a gas guide member 680 is disposed above the upper electrode 170 such that the flow path 171 (refer to FIG. 2) of the upper electrode 170 (refer to FIG. 2) and the first gas inlet 112 (refer FIG. 2) are connected to each other. As an example, the gas guide member 680 may be fixedly installed on an upper surface of the upper electrode 170. Meanwhile, the gas guide member 680 includes a body 682 having a side supply port 682a, and a gas guide portion 684 insertedly coupled to an inside of the body 682 and provided with a flow path hole 684a and a plurality of guide holes 684b. In other words, the gas guide member 680 may have a hollow cylindrical shape having a flow path hole 684a penetrating in upward and downward directions, and may be provided with at least two side supply ports 682a into which gas is introduced to an external side surface thereof. In addition, a plurality of guide holes 684b for allowing the gas introduced through the side supply port 682a to be introduced into the flow path hole 684a of the gas guide member 680 may be provided on an inner surface of the gas guide member 680. Meanwhile, the gas introduced into the first gas inlet 112 and the side supply port 682a may be mixed in the flow path hole 684a.

As an example, the plurality of guide holes 684b may be disposed to form a plurality of rows. In addition, the plurality of guide holes 684b may be circumferentially spaced apart from each other to have the same angle therebetween.

Meanwhile, the body 682 and the gas guide portion 684 forms a flow path 686 through which the gas introduced into the side supply port 682a is discharged to the plurality of guide holes 684b. The flow path 686 is formed to have an internal space of a predetermined volume. In addition, the flow path 686 may have an annular shape and a rectangular cross-section. As described above, since the flow path 686 is formed to have an internal space of a predetermined volume, the gas introduced into the flow path 686 may be discharged to a plurality of guide holes 684b at a constant pressure. As an example, the plurality of guide holes 684b may form three rows in an upper end portion, a central portion, and a lower end portion of the flow path 686 in approximately upper and lower directions.

In addition, a first stepped portion 684c for bonding to the body 682 is provided in an upper end portion of an outer circumferential surface of the gas guide portion 684, and a second stepped portion 684d may be provided in a lower end portion of the outer circumferential surface of the gas guide portion 684 for bonding to the body 682. First and second stepped portions 684c and 684d may be bonded to the body 682 by welding. However, the present inventive concept is not limited thereto and may be bonded to the first and second stepped portions 684c and 684d by an adhesive.

Meanwhile, a diameter of an upper portion of the flow path hole 684a of the gas guide portion 684 may be formed to be larger than a diameter of a lower portion thereof, and the diameter of a lower end portion of the flow path hole 684a may be smaller toward a lower side thereof. Accordingly, the gas introduced from the first gas inlet 112 and the gas introduced into the guide hole 684b may be supplied more smoothly to the lower upper electrode 170, the baffle 160 (refer to FIG. 2) and the shower head 150 (refer to FIG. 2).

The side supply port 682a provided in the body 682 may be provided with a first side supply port 682a-1 connected to the flow path 686 formed by the body 682 and the gas guide portion 584, and a second side supply port 682a-2 having a larger size than the first side supply port 682a-1 and connected to the flow path 686. As an example, the first side supply port 682a-1 serves as a passage through which a gas used for a deposition process is introduced, and the second side supply port 682a-2 serves as a passage through which cleaning gas is introduced during maintenance and repair of the deposition apparatus after the process is completed.

As set forth above, a deposition apparatus capable of reducing gas supplied to a wafer from being deflected and supplied to the wafer may be provided.

Herein, a lower side, a lower portion, a lower surface, and the like, are used to refer to a direction toward a mounting surface of the fan-out semiconductor package in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an adhesive layer as well as a direct connection between two components. In addition, “electrically connected” conceptually includes a physical connection and a physical disconnection. It can be understood that when an element is referred to with terms such as “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein.

Similarly, a second element may also be referred to as a first element.

The term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

Terms used herein are used only in order to describe an example embodiment rather than limiting the present disclosure. In this case, singular forms include plural forms unless interpreted otherwise in context.

While example embodiments have been shown and described above, it will be apparent to those skilled in the art that modifications and variations could be made without departing from the scope of the present inventive concepts as defined by the appended claims.

What is claimed is:

1. A deposition apparatus, comprising:
a chamber having at least one first gas inlet therein and having an interior space;
a fixed chuck in the chamber;
an electrostatic chuck on the fixed chuck;
an edge ring on an edge of the electrostatic chuck;
a shower head above the edge ring;
a baffle above the shower head;
an upper electrode above the baffle and including a flow path therein;
a gas guide member above the upper electrode and connecting the flow path provided in the upper electrode with the first gas inlet;
the gas guide member has a hollow cylindrical shape having a flow path hole therethrough, and at least two side supply ports into which gas is introduced are provided on an external side surface thereof,
an inner surface of the gas guide member includes a plurality of guide holes in communication with the at least two side supply ports and the flow path hole of the gas guide member, and
wherein the gas introduced into the first gas inlet and the at least two side supply ports is mixed in the flow path hole.

2. The deposition apparatus of claim 1, wherein the plurality of guide holes form one row.

3. The deposition apparatus of claim 2, wherein the gas guide member includes a body having the at least two side supply ports, and a gas guide portion insertedly coupled to an inside of the body and having the flow path hole and the plurality of guide holes.

4. The deposition apparatus of claim 3, wherein the body and the gas guide portion form a flow path through which the gas introduced into the side supply port is discharged to the plurality of guide holes.

5. The deposition apparatus of claim 4, wherein the flow path has an annular shape, and has a rectangular cross-section.

6. The deposition apparatus of claim 4, wherein the plurality of guide holes are disposed in a central portion of the flow path in upward and downward directions.

7. The deposition apparatus of claim 6, wherein the plurality of guide holes are circumferentially spaced at a same interval.

8. The deposition apparatus of claim 7, wherein the plurality of guide holes have an angle between neighboring guide holes of 15 degrees.

9. The deposition apparatus of claim 8, wherein the plurality of guide holes have a diameter of between 1 to 2 mm.

10. The deposition apparatus of claim 3, wherein a first stepped portion is provided in an upper end portion of an outer circumferential surface of the gas guide portion for bonding to the body, and
a second stepped portion is provided in a lower end portion of the outer circumferential surface of the gas guide portion for bonding to the body.

11. The deposition apparatus of claim 3, wherein the flow path hole of the gas guide portion is formed to have an upper diameter to be larger than a lower diameter thereof, and a lower end portion of the flow path hole has a tapering diameter toward a lower side.

12. The deposition apparatus of claim 3, wherein the at least two side supply ports provided in the body include a first side supply port disposed on one side of the body, and a second side supply port having a size, larger than that of the first side supply port.

13. The deposition apparatus of claim 1, wherein the plurality of guide holes are to form a plurality of rows.

14. The deposition apparatus of claim 4, wherein the plurality of guide holes are in an upper end portion of the flow path in upward and downward directions.

15. The deposition apparatus of claim 4, wherein the plurality of guide holes are in a lower end portion of the flow path in upward and downward directions.

16. The deposition apparatus of claim 4, wherein the flow path has an annular shape, and has a trapezoidal cross-section.

17. A deposition apparatus, comprising:
a chamber having a plurality of first gas inlets on an upper surface and having an internal space;
a fixed chuck in the chamber and having an installation groove;
an electrostatic chuck in the installation groove of the fixed chuck;
an edge ring on an edge of the electrostatic chuck;
a shower head above the edge ring;
a baffle above the shower head;
an upper electrode above the baffle and including a flow path therein;
a gas guide member disposed above the upper electrode to connect the flow path provided in the upper electrode and the first gas inlet,
the gas guide member includes,
a body having a cylindrical shape and having at least two side supply ports in an outer circumferential surface thereof, and
a gas guide portion in the body and having a flow path hole through which gas introduced through first and second gas inlets passes, a flow path through which gas introduced through the at least two side supply ports temporarily remains together with an inner circumferential surface of the body, and a plurality of guide holes connecting the flow path and the flow path hole,
wherein the plurality of guide holes are circumferentially spaced apart from each other.

18. The deposition apparatus of claim 17, wherein the plurality of guide holes are in a central portion of the flow path in a longitudinal direction.

19. The deposition apparatus of claim 18, wherein the flow path has an annular shape, and a rectangular cross-section.

20. The deposition apparatus of claim 18, wherein the plurality of guide holes form one row.
